(19) United States
(12) Patent Application Publication
(10) Pub. No.: US 2007/0052098 A1
(43) Pub. Date: Mar. 8, 2007

(54) Metal line for a semiconductor device and fabrication method thereof

(76) Inventors: Sung Joong Joo, Seoul (KR); Han Choon Lee, Seoul (KR)

Correspondence Address: MCKENNA LONG & ALDRIDGE LLP;Song K. Jung, 1900 K Street, N.W., Washington, DC, 20006, US

(21) Appl. No.: 11/320,763

(22) Filed: Dec. 30, 2005

(30) Foreign Application Priority Data
Aug. 29, 2005 (KR) 10-2005-0079507

(51) Int. Cl. H01L 23/52; H01L 21/4763

(52) U.S. Cl. 257/751; 438/627; 257/762; 257/E23.145

(57) ABSTRACT

A metal line, which can be used in a semiconductor device structure less than 65 nm in size by forming a barrier metal of an anti-diffusion layer for a copper line using CVD TiSiN, and a fabrication method thereof are provided. The metal line includes: a semiconductor substrate having a semiconductor device formed thereon; an insulating layer which has a contact hole at a portion corresponding to the semiconductor device and is formed on the semiconductor substrate; a TiSiN barrier metal layer which is formed in the contact hole; and a copper line which is formed on the TiSiN barrier metal layer.

### CROSS REFERENCE TO RELATED APPLICATIONS

This application claims the benefit of the Korean Patent Application No. P2005-0079507, filed on Aug. 29, 2005, which is hereby incorporated by reference as if fully set forth herein.

### BACKGROUND OF THE INVENTION

1. Field of the Invention

The present invention relates to a copper line for a semiconductor device, and more particularly, to a metal line for a semiconductor device in which a barrier metal used as an anti-diffusion layer for the copper line is formed using CVD TiSiN, and a fabrication method thereof.

2. Description of the Related Art

As the size of semiconductor devices has recently decreased, the line width and thickness of a metal line for a semiconductor device has also decreased. To cope with the reduction of the line width and thickness of the semiconductor device, aluminum (Al) has been widely used as a material for the metal line.

However, since the Al has a relatively high resistivity, it has been known that the Al is not an appropriate metal for lines in ultra large scale integration (ULSI) and giga scale integration (GSI).

Recently, therefore, copper (Cu) having a low resistivity and an excellent electromigration has been widely researched as an alternative material to Al metal lines.

However, when using copper, dry etching cannot not be easily performed, copper's adhesion characteristic with respect to a silicon oxide layer (SiO₂) is not good, and the thermodynamic stability and corrosion resistance of copper are low.

Furthermore, copper rapidly diffuses in silicon (Si) and SiO₂ and generates a leakage current in a pn-junction by forming a deep donor level in the Si, causing a malfunction of the semiconductor device. Thus, an anti-diffusion layer is required to effectively prevent the diffusion of Cu. In particular, when copper is used for a metal line in the ULSI, a resistance of the line must be minimized and the thickness of the anti-diffusion layer has to be less than 100 Angstroms. Thus, research on the anti-diffusion layer is necessary to find an effective way to control the diffusion of copper even when the thickness of the anti-diffusion layer is thin.

In order to function as a stable anti-diffusion layer, to prevent the diffusion of copper the barrier metal has to be more than 50 Angstroms in thickness.

When the barrier metal is deposited by a sputtering method or a physical vapor deposition (PVD) method, the barrier metal has to be deposited in a thickness greater than 100 Angstroms to achieve a thickness greater than 50 Angstroms on the side wall of a via. However, when the barrier metal is deposited to a thickness greater than 100 Angstroms by sputtering in a semiconductor device structure that is less than 65 nm in size, an overhang is inevitably created at the upper side of the via or trench. Thus, a problem such as void may occur in integrating with the copper.

As a result, a barrier metal formation using the sputtering method is limited to semiconductor device structures that are 65 nm in size or larger.

Recently, to solve the above-mentioned problems, a deposition method for a barrier metal layer using an atomic layer deposition (ALD) and a chemical vapor deposition (CVD) have been actively researched.

Compared with the deposition using a PVD method, it has been found that the deposition using an ALD method or a CVD method has a much better step coverage, and thereby can deposit a thin and uniform barrier metal layer even in a via less than 65 nm in size.

A structure of a copper metal line and a fabrication method thereof according to the prior art will now be described.

Hereinafter, a metal line for a semiconductor device and a metal line forming method according to the prior art will be described in reference with the accompanying drawings.

FIGS. 1A to 1D are sectional views of a semiconductor device fabricated in accordance with a prior art processes for forming a metal line.

As shown in FIG. 1, impurity ions are implanted in a semiconductor substrate 1 to form a semiconductor device 2.

Next, an insulating layer 3 such as a nitride oxide layer, an oxide layer, or BPSG is formed on the whole surface of the semiconductor substrate 1 including the semiconductor device 2.

A first photoresist 4 is coated on the insulating layer 3, and a contact area is then defined by patterning the first photoresist 4 by exposing and developing processes.

Next, a contact hole 5 is formed by selectively removing the insulating layer 3 using the patterning first photoresist 4 as a mask.

As shown in FIG. 1B, the first photoresist 4 is removed, a second photoresist 6 is coated on the whole surface of the semiconductor substrate 1 including the contact hole 5, and the second photoresist 6 is then subject to the patterning by exposing and developing processes.

Next, a trench 7 is formed by selectively removing the insulating layer 3 by a predetermined depth using the patterned second photoresist 6 as a mask.

Trench 7 is formed to have a wider width than the contact hole 5.

As shown in FIG. 1C, a barrier metal layer 8, on which titanium nitride (TiN) and titanium (Ti) are laminated, is formed on the whole surface of the semiconductor substrate 1 including the trench 7 and the contact hole 5.

The barrier metal layer 8 is formed using a PVD method, and the TiN layer and Ti layer respectively have the thickness of 150 Angstroms.

A Cu seed layer is then formed on the barrier metal layer 8, and a copper thin layer 9 is then formed using an electroplating method.

As shown in FIG. 1D, the copper thin layer 9 and the barrier metal layer 8 are grinded to expose the surface of the insulating layer 3, thereby forming a copper line 9a and a barrier line 8a in the trench 7 and the contact hole 5.

The method of forming a metal line in a semiconductor device of the prior art has the following problems.

First, as mentioned above, since the barrier metal layer is formed using a PVD method, the barrier metal layer is not uniformly deposited.

Second, since the barrier metal layer is formed using a PVD method, it is difficult to deposit a barrier metal layer that is less than 100 Angstroms thick. Thus, it cannot be used in a semiconductor device structure that is less than 65 nm in size.

### SUMMARY OF THE INVENTION

Accordingly, the present invention is directed to a metal line for a semiconductor device and fabrication method thereof that substantially obviates one or more problems due to limitations and disadvantages of the related art.

An advantage of the present invention is that it provides a metal line for a semiconductor device which can be used in a semiconductor device structure less than 65 nm deep using CVC TiSiN as a material for a barrier metal layer, and a fabrication method thereof.

Additional advantages and features on the invention will be set forth in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described, a metal line for a semiconductor device comprising: a semiconductor substrate having a semiconductor device formed thereon; an insulating layer which has a contact hole at a portion corresponding to the semiconductor device and is formed on the semiconductor substrate; a TiSiN barrier metal layer which is formed in the contact hole; and a copper line which is formed on the TiSiN barrier metal layer.

According to another aspect of the present invention, a metal line for a semiconductor device comprises a semiconductor substrate having a semiconductor device formed thereon; an insulating layer which has a contact hold at a portion corresponding to the semiconductor device is formed on the semiconductor substrate; a barrier metal layer which consists of a TiSiN layer formed in the contact hold and a Ta layer laminated on the TiSiN; and a copper line which is formed on the barrier metal layer.

According to another aspect of the present invention, a method of fabricating a metal line for a semiconductor device comprising steps of: forming a semiconductor device on a semiconductor substrate; forming a contact hole at a portion corresponding to the semiconductor device by depositing an insulating layer on the semiconductor substrate and selectively removing the insulating layer; forming a TiSiN barrier metal layer formed on the whole surface of the semiconductor substrate including the contact hole; forming a copper layer on the TiSiN barrier metal layer; and grinding the copper layer and the TiSiN barrier metal layer to expose the surface of the insulating layer.

In the aforementioned aspect of the method, the step of forming the TiSiN barrier metal layer may further comprise: a first step of depositing a thermal TiN layer using a tetrakis dimethyl amino titanium (TDMAT) material; a second step of forming a CVD nitride titanium (TiN) layer by performing a plasma process on the thermal TiN; and a third step of forming a CVD TiSiN layer by reacting SiH₄ gas with the CVD TiN layer.

According to another aspect of the present invention, there is provided a method of fabricating a metal line for a semiconductor device comprising steps of: forming a semiconductor device on a semiconductor substrate; forming a contact hole at a portion corresponding to the semiconductor device by depositing an insulating layer on the semiconductor substrate and selectively removing the insulating layer; forming a TiSiN barrier metal layer on the whole surface of the semiconductor substrate including the contact hole; forming a Ta layer on the TiSiN layer; forming a copper layer on the Ta layer; and

grinding the copper layer, the TiSiN layer, and the Ta layer to expose the surface of the insulating layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIGS. 1A to 1D are sectional views of a semiconductor device fabricated in accordance with a prior art process of forming a copper line;

FIGS. 2A to 2F are sectional views of a semiconductor device fabricated with a process of forming a copper line in accordance with an exemplary embodiment of the present invention;

FIGS. 3A to 3C are graphs illustrating a results of a copper diffusion with respect to a barrier metal layer structure of an exemplary embodiment of the present invention, in which FIG. 3A is a view illustrating the results for a structure of a metal line of the prior art, Cu/Ta/TaN/FSG, FIG. 3B is a view illustrating a structure of a metal line of Cu/TISiN/FSG according to a first embodiment of the present invention, and FIG. 3C is a view illustrating a structure of a metal line of Cu/TiSiN/FSG according to a second embodiment of the present invention;

FIGS. 4A and 4B are graphs illustrating results of a copper diffusion after a barrier metal layer of an exemplary embodiment of the present invention is annealed, in which FIG. 4A shows the results a structure of a barrier metal layer of an exemplary embodiment of the present invention, Cu/TiSiN/Low-k, and FIG. 4B shows the results a structure of the prior art, Cu/Ta/TiN/Low-k;

FIGS. 5A to 5C show results of analyzing characteristics of a barrier metal layer of exemplary embodiments of the present invention and a copper adhesion, in which FIG. 5A shows the results for a metal line structure of the prior art, Cu/Ta/TiN, FIG. 5B shows the results for a metal line structure, Cu/TiSiN, according to a first embodiment of the present invention, and FIG. 5C shows the results for a metal line structure, Cu/Ta/TiSiN, according to a second embodiment of the present invention.

FIGS. 6A and 6D show a result of analyzing a chain resistance of exemplary embodiments of the present invention, in which FIG. 6A shows a case of not using a punch-though process in a Ta/TiN structure of the prior art, FIG. 6B shows a case of using a punch-though process in a Ta/TiN structure of the prior art, FIG. 6C shows case of not using a punch-though process in a TiSiN structure of the present invention, and FIG. 6D shows case of using a punch-though process in a TiSiN structure of the present invention.

FIGS. 7A to 7D show a result of analyzing a Kelvin resistance of exemplary embodiments of the present invention, in which FIG. 7A shows a result for the case of not using a punch-through process in the Ta/TiN structure of the prior art, FIG. 7B shows a result of the case of using a punch-through process in the Ta/TiN structure of the prior art, FIG. 7C shows a result for the case of not using a punch-through process in the TiSiN structure of the present invention, and FIG. 7D shows a result for the case of using a punch-through process in the TiSiN structure of the present invention.

FIGS. 8A to 8D show a result of analyzing a resistance distribution based on a line width of a barrier metal layer of exemplary embodiments of the present invention, in which FIG. 8A shows a result for the case of not using a punch-through process in the Ta/TiN structure according to the prior art, FIG. 8B shows a result of the case of using a punch-through process in the Ta/TiN structure of the prior art, FIG. 8C shows a result for the case of not using a punch-through process in the TiSiN structure of the present invention, and FIG. 8D shows a result for the case of using a punch-through process in the TiSiN structure of the present invention.

FIGS. 9A to 9C show a result of analyzing a leakage current based on a temperature of a barrier metal layer of exemplary embodiments of the present invention, in which FIG. 9A shows a result for the case of a single structure of TiSiN according to a first embodiment of the present invention, FIG. 9B shows a result for the case of the Ta/TiSiN structure according to a second embodiment of the present invention, and FIG. 9C shows a result for the case of the Ta/TiN structure according to the prior art.

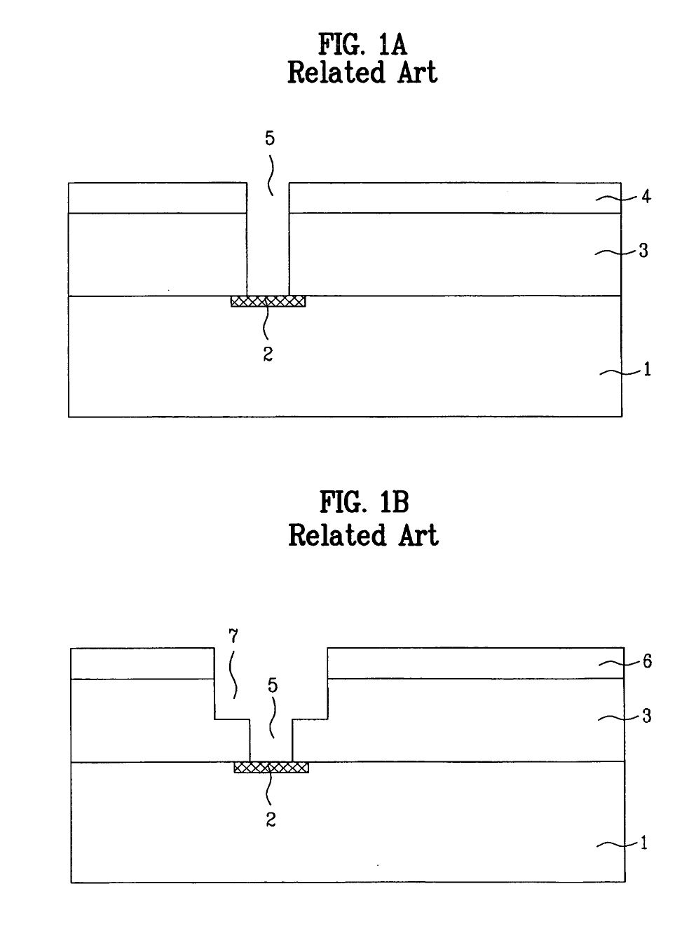

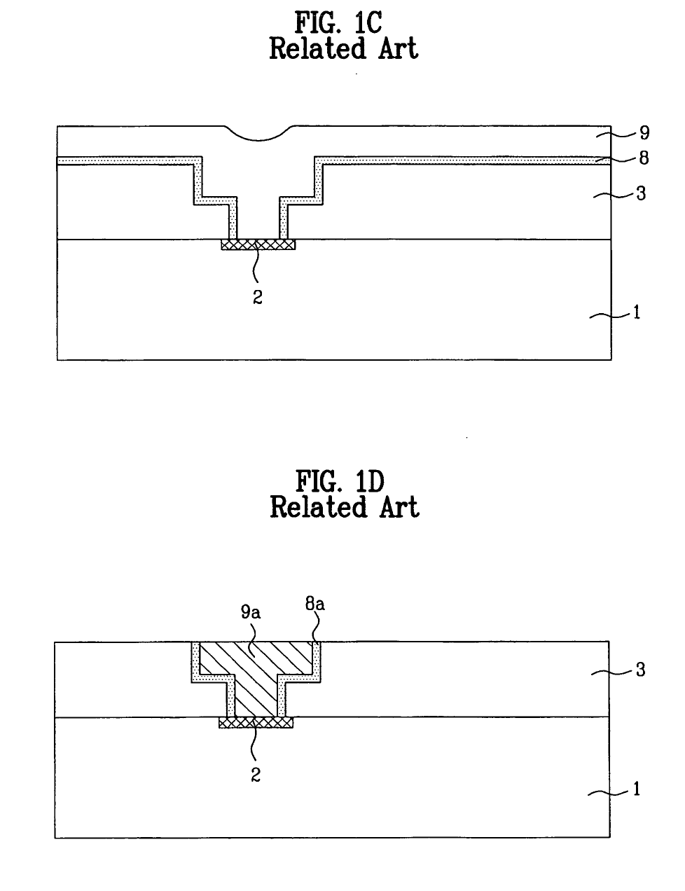

### DETAILED DESCRIPTION OF THE PREFERRED EMBODIMENTS

Reference will now be made in detail to exemplary embodiments of the present invention, examples of which are illustrated in the accompanying drawings.

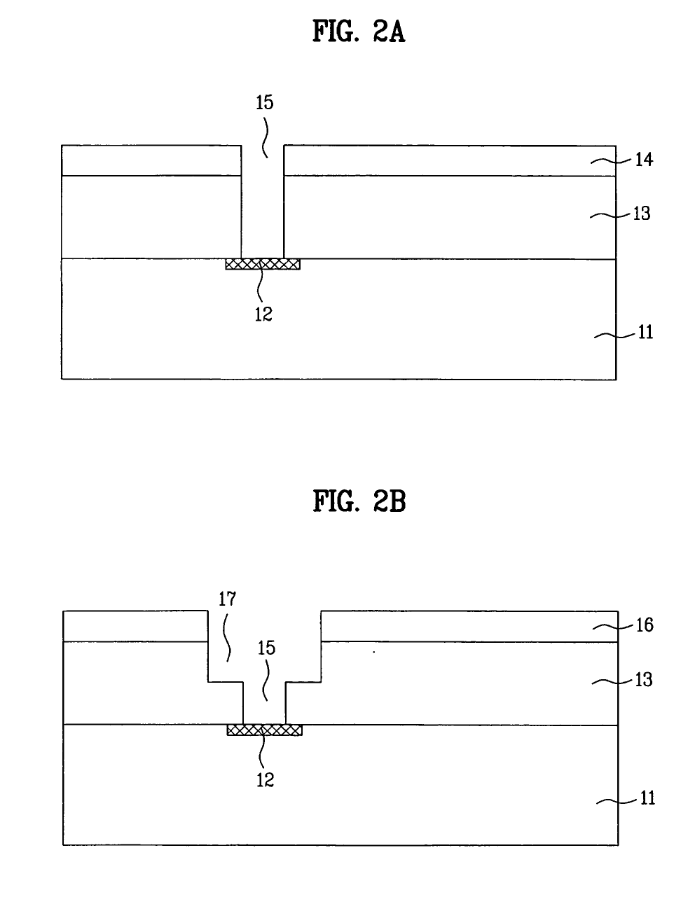

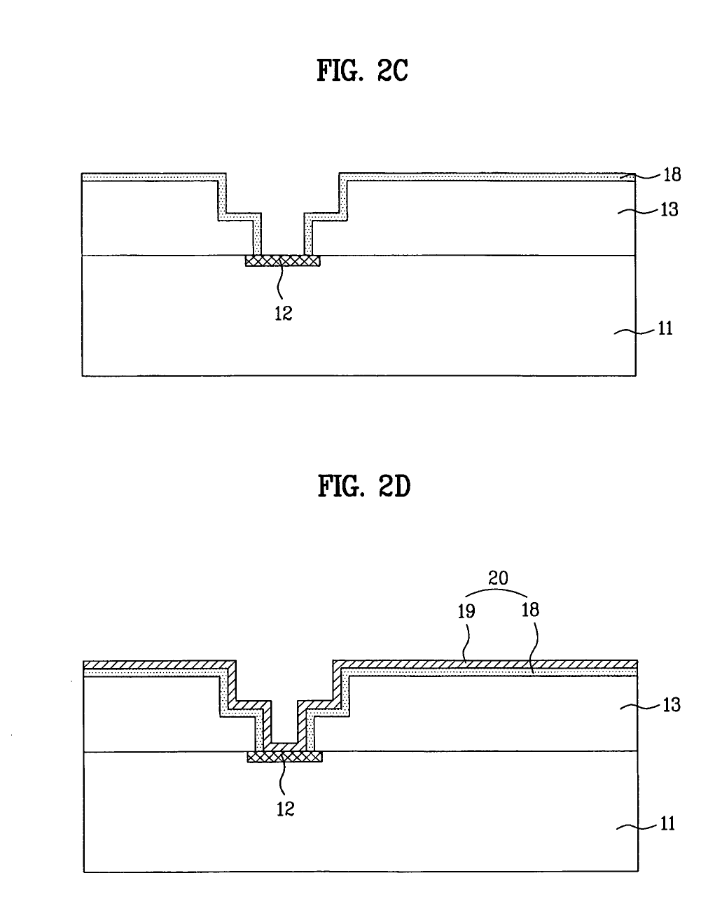

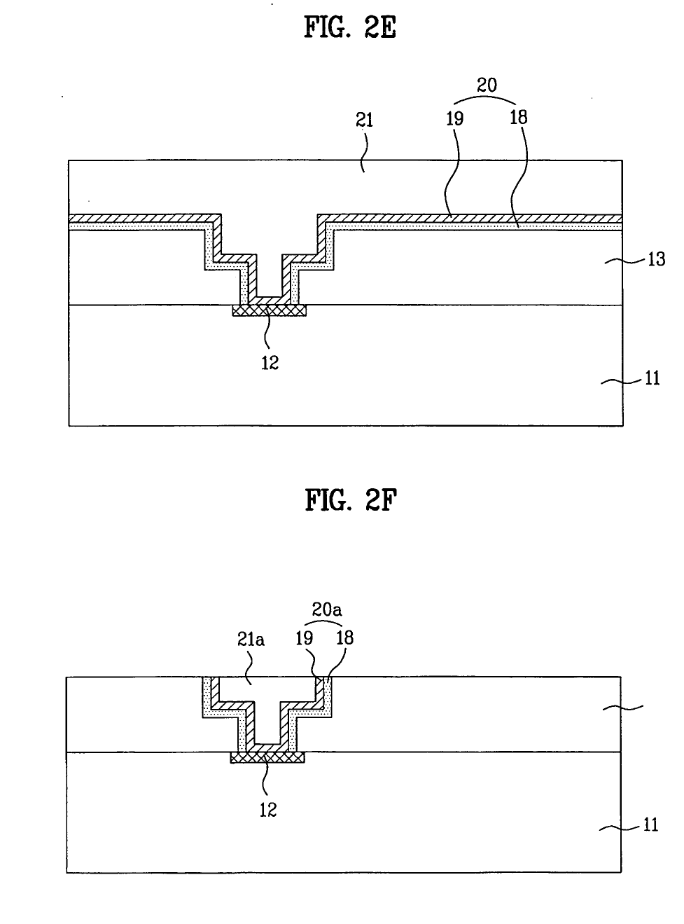

FIGS. 2A to 2D are sectional views of a semiconductor device fabricated with a process of forming a copper line in accordance with an exemplary embodiment of the present invention.

As shown in FIG. 2A, impurity ions are implanted in a semiconductor substrate 11 to form a semiconductor device 12.

Next, an insulating layer 13 such as a nitride oxide layer, an oxide layer, FSG, or BPSG is formed on the whole surface of the semiconductor substrate 11 including the semiconductor device 12.

A first photoresist 14 is coated on the insulating layer 13, and a contact area is then defined by patterning the first photoresist 14 by exposing or developing processes.

Next, a contact hole 15 is formed by selectively removing the insulating layer 13 using the patterned first photoresist 14 as a mask.

As shown in FIG. 2B, the first photoresist 14 is removed, a second photoresist 16 is coated on the whole surface of the semiconductor substrate 11 including the contact hole 15, and the second photoresist 16 is then subject to the patterning by the exposing and developing processes.

Next, a trench 17 is formed by selectively removing the insulating layer 13 by a predetermined depth using the patterned second photoresist 16 as a mask.

In this manner, a contact is formed with a dual damascene structure in which the trench 17 has a wider width than the contact hole 15.

As shown in FIG. 2C, a titanium silicon nitride (TiSiN) layer 18 is formed on the whole surface of the semiconductor substrate 11 including the trench 17 and the contact hole 15.

A method of forming the TiSiN layer 18 will be described in detail.

First, a thermal TiN layer is deposited over the semiconductor substrate 11 around 50 Angstroms in thickness using a tetrakis dimethyl amino titanium (TDMAT) material, and a CVD titanium nitride (TiN) layer is then formed by a plasma process. Since the thickness of the thermal TiN layer decreases in the plasma process, the CVD TiN layer is around 25 Angstroms thick.

The aforementioned process is repeated to form the CVD TiN layer having the thickness of around 50 Angstroms. Of course, the CVD TiN layer may have a desired thickness by performing the process only one time, and the CVD nitride TiN may have 30 to 100 Angstroms by controlling the thickness of the thermal TiN layer.

Next, a CVD TiSiN layer 18 is formed by reacting SiH₄ gas with the CVD TiN layer in a condition that a temperature of the semiconductor substrate is maintained to be 300 to 400° C. (for example around 350° C.).

A punch-through process that selectively removes the TiSiN layer 18 formed at the bottom of the contact hole 15 is performed on the TiSiN layer 18 by generating argon plasma. The punch-through process, however, is optional.

As shown in FIG. 2D, a tantalum (Ta) layer 19 is formed of about 30 to 100 Angstroms in thickness (for example 75 Angstroms) over the whole surface of the semiconductor substrate 11 including the CVD TiSiN layer 18, to form a barrier metal layer 20 in which the TiSiN layer 18 and the Ta layer 19 are laminated. A punch-through process may also be used to selectively remove the Ta layer formed at the bottom of the contact hole by using an argon plasma.

Instead of forming the Ta layer 19, the barrier metal layer 20 may alternatively be a single layer of TiSiN.

As shown in FIG. 2E, a Cu seed layer is formed on the barrier metal layer 20, and a Cu thin layer 21 is then formed using an electroplating method.

As shown in FIG. 2F, the Cu thin layer 21 and the barrier metal layer 20 are grinded to expose the surface of the insulating layer 13, thereby forming a copper line 21a and a barrier line 20a in the trench 20a and the contact hole 15.

A metal line for a semiconductor device has been formed as described above, and then metal lines according to the prior art and the present invention have been tested and compared. This will be described in detail below.

Characteristics of diffusion, adhesion, step coverage, and resistance have been tested and compared.

A thermal oxide layer has been formed on a P-type semiconductor substrate around 1,000 Angstroms in thickness, and FSG or Low-k dielectric material has been deposited thereon. Next, in order to test and compare the characteristics of the barrier metal layer, a barrier metal layer used in 130 nm level, Ta(150 Angstroms)/TaN(150 Angstroms), and a barrier metal layer of the present invention, TiSiN(50 Angstroms) and Ta(75 Angstroms)/TiSiN (50 Angstroms), are respectively deposited, and then the characteristics of the battier metal layers have been analyzed as follows.

In order to check the diffusion degree of the Cu in a process of depositing the Cu seed on the barrier metal layer, the Cu seed has been deposited to be 600 Angstroms, the Cu/barrier metal has been then removed by the CMP, and the amount of the Cu remaining in the FSG has been then quantitatively analyzed using the VPD method. The characteristics of the anti-diffusion layer for the Cu in a following annealing process has been analyzed by AES. For a split condition, an annealing process has been performed for 30 minutes at 350° C. on the FSG, and at 400° C., 500° C., and 600° C. on the Low-k dielectric material.

A table 1 below shows a diffusion degree of the Cu in the copper deposition process measured by the VPD with respect to a barrier metal layer of the prior art, Ta(150 Angstroms)/TaN(150 Angstroms), and a barrier metal layer of the present invention, TiSiN(50 Angstroms) and Ta(75 Angstroms)/TiSiN(50 Angstroms), formed on the FSG.

TABLE 1

| Barrier metal layer | Cu diffusion (atom/cm²) |
|---|---|
| Ta(150 Angstroms)/TaN(150 | 6.78E+12 |
| Angstroms) | |
| TiSiN(50 Angstroms) | 8.11E+12 |
| Ta(75 Angstroms)/TiSiN(50 | 4.06E+12 |
| Angstroms) | |

As shown in table 1, the barrier metal layer of the present invention has a much better diffusion characteristic.

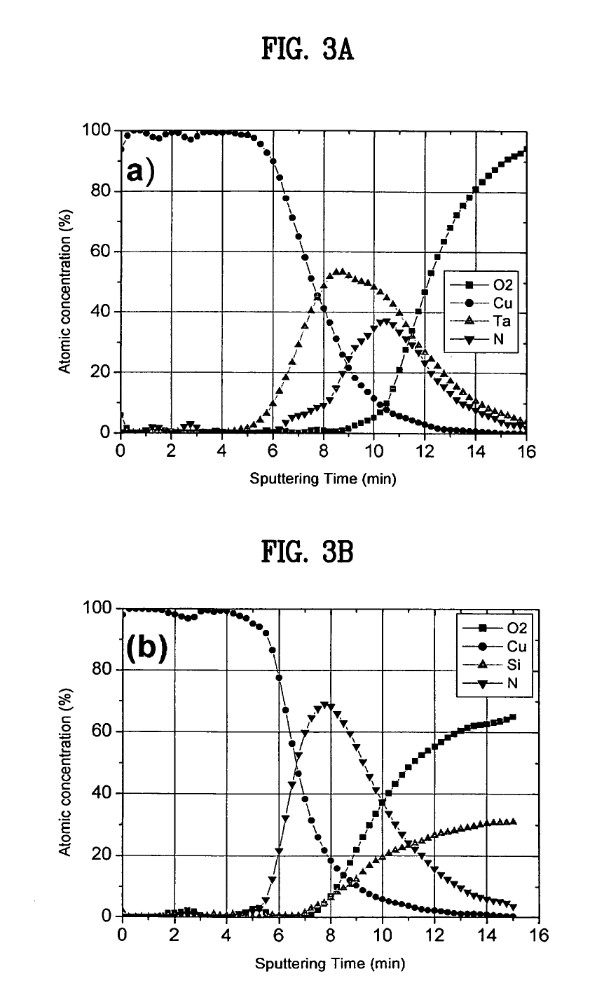

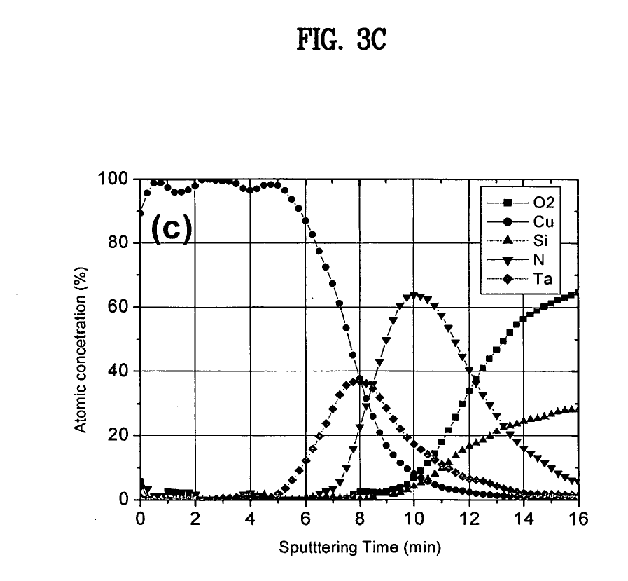

In addition, the Cu was deposited on the barrier metal layer of the prior art, Ta(150 Angstroms)/TaN(150 Angstroms), and a barrier metal layer of the present invention, TiSiN(50 Angstroms) and Ta(75 Angstroms)/TiSiN(50 Angstroms), formed on the FSG, an annealing process has performed thereon, and the Cu diffusion degree has been analyzed by AES, which can be seen in FIGS. 3A to 3C.

The annealing process was performed for 30 minutes at 350° C. In the barrier metal layer of the present invention, TiSiN(50 Angstroms) and Ta(75 Angstroms)/TiSiN(50 Angstroms), a Cu component has disappeared at a sputtering time of 14 minutes, which is a similar characteristic of the barrier metal layer of the prior art.

FIG. 3A is a view illustrating the results of copper diffusion for a structure of a metal line of the prior art, Cu/Ta/TaN/FSG. FIG. 3B is a view illustrating the results for a structure of a metal line of Cu/TiSiN/FSG according to a first embodiment of the present invention. FIG. 3C is a view illustrating the results for a structure of a metal line of Cu/TiSiN/FSG according to a second embodiment of the present invention.

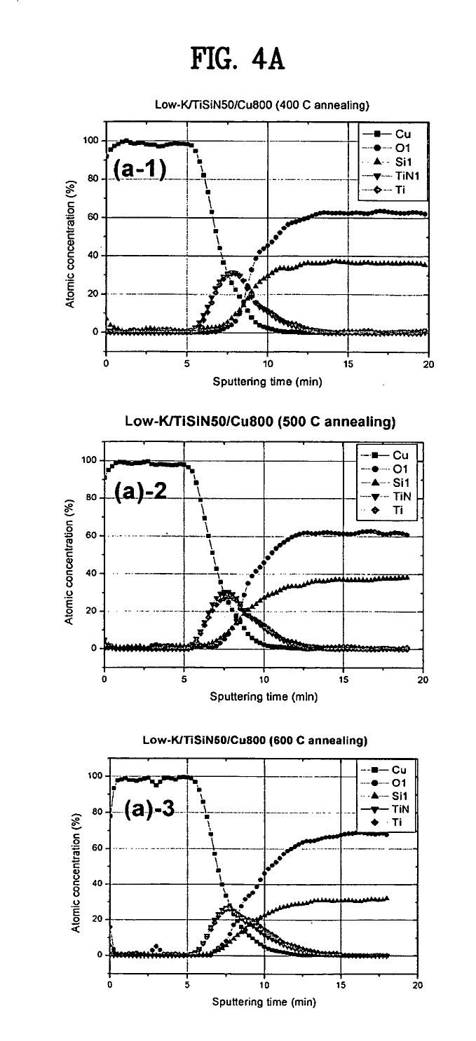

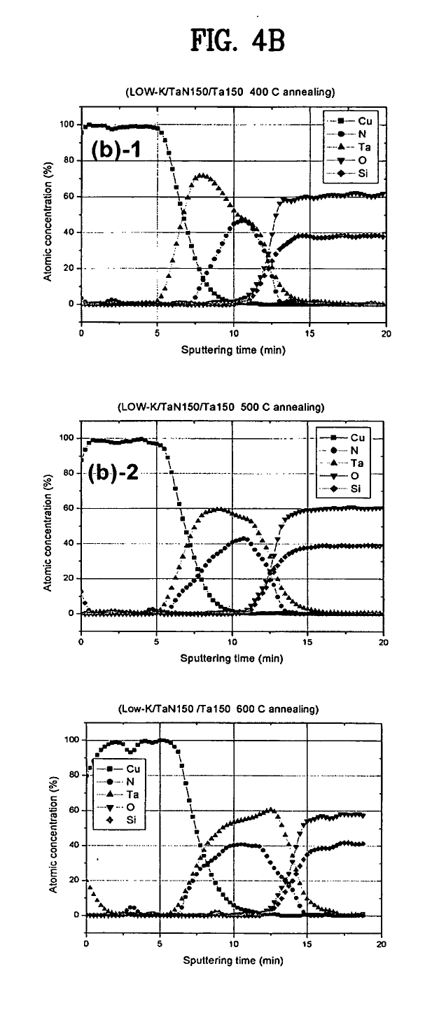

In addition, in order to know the Cu diffusion degree in the Low-k material with respect to a barrier metal layer of the prior art, Ta/TiN, and a barrier metal layer of the present invention, TiSiN, an annealing process was performed for 30 minutes at 400° C., 500° C., and 600° C., which can be seen in FIGS. 4A and 4B.

Namely, FIG. 4A shows the results for a structure of a barrier metal layer of the present invention, Cu/TiSiN/Low-k, and FIG. 4B shows the results for a structure of the prior art, Cu/Ta/TiN/Low-k.

As shown in FIG. 4, it can be seen that, the Cu diffusion degree of the TiSiN barrier metal layer of the present invention becomes stable in a Low-k material in response to a temperature change, as in the case of the prior art.

Next, an adherence characteristic was compared.

An adhesion characteristic of the barrier metal layer has been confirmed through a tape test. The adhesion characteristic after the annealing process performed has been indirectly measured using a SEM image and reflectivity. According to the results, Cu peeling has not been found at both center portion and corner portion.

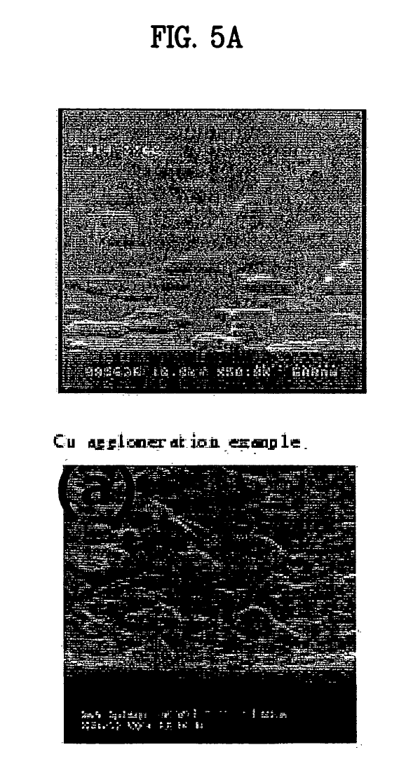

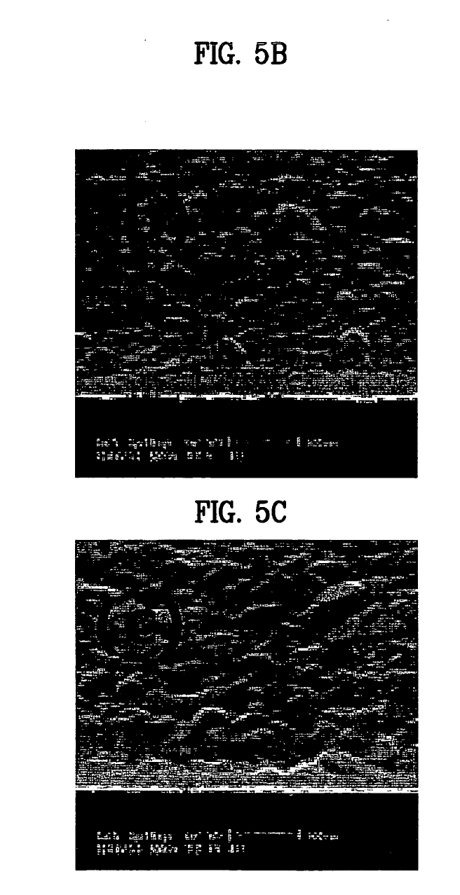

In order to test the adhesion characteristic of the barrier metal layer and the Cu according to the prior art and present invention, the metal line has been annealed for 30 minutes at 350° C., and the surface of the Cu has been analyzed using a SEM image, which can be seen in FIGS. 5A to 5C.

FIG. 5A shows a result of a metal line structure of the prior art, Cu/Ta/TiN. FIG. 5B shows the results for a metal line structure, Cu/TiSiN, according to a first embodiment of the present invention. FIG. 5C shows the results for a metal line structure, Cu/Ta/TiSiN, according to a second embodiment of the present invention.

It can be seen that, unlike the prior art, Cu agglomeration has not been found in the exemplary embodiments of the present invention.

In addition, the reflectivity has been analyzed before and after the annealing process with respect to the barrier metal layers of the prior art and the exemplary embodiment of the present invention. According to the results, in the barrier metal layer of the exemplary embodiments of the present invention, reflectivity of both TiSiN and Ta/TiSiN structures are greater than 90%. Thus, it has been confirmed that the Cu agglomeration does not occur.

The TiSiN (50 Angstroms) of an exemplary embodiment of the present invention was analyzed by EELS in order to confirm the step coverage of the barrier metal layer with respect to the bottom and the side wall of the contact hole. According to the result, it was confirmed that the Ti and N components were uniformly deposited on the bottom and the side wall of the contact hole.

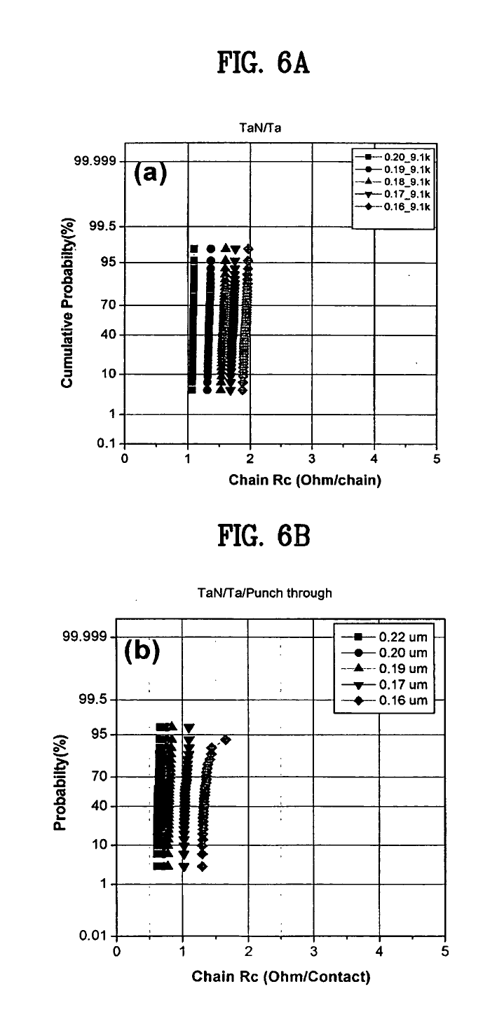

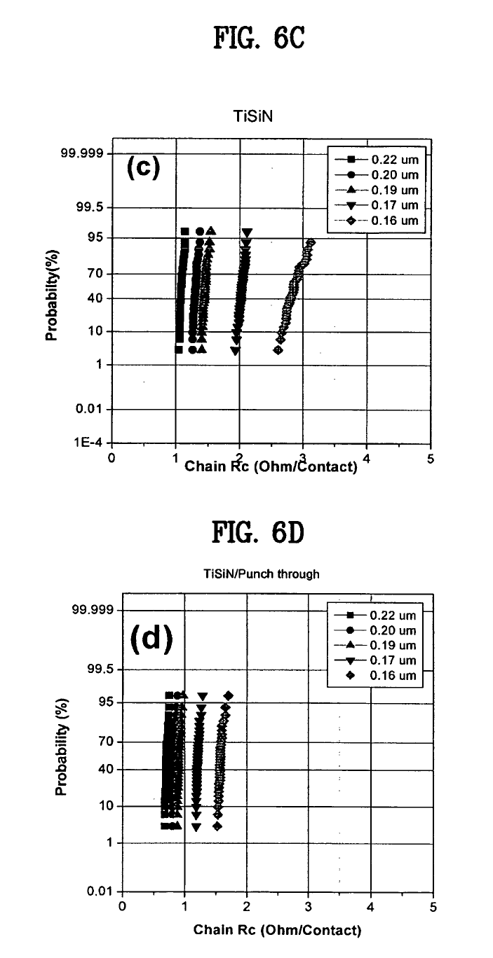

In addition, chain resistances was analyzed with respect to the barrier metal layers according to the prior art and an exemplary embodiment of the present invention, which can be seen in FIGS. 6A to 6D with and without a punch-through process.

FIG. 6A shows results associated with not using a punch-though process in a Ta/TiN structure of the prior art. FIG. 6B shows the results with using a punch-through process in a Ta/TiN structure of the prior art. FIG. 6C shows case of not using a punch-through process in a TiSiN structure of the present invention. FIG. 6D shows results with using a punch-through process in a TiSiN structure of the present invention.

Referring to FIGS. 6A and 6B, when the punch-through process is used in the Ta/TaN structure, the chain resistance of around 2 (ohm/chain) at the minimum 0.18 um CD size decreases to around 1.5 (ohm/chain), that is 25% reduction.

Referring to FIGS. 6C and 6D, when the punch-through process is used on the barrier metal layer of the present invention, the chain resistance may be decreased from around 2.7 (ohm/chain) to around 1.5 (ohm/chain), that is a 45% reduction. Also, it has been confirmed that, if the punch-through process is used in the TiSiN structure, tail that occurs at 0.18 um CD size decreases.

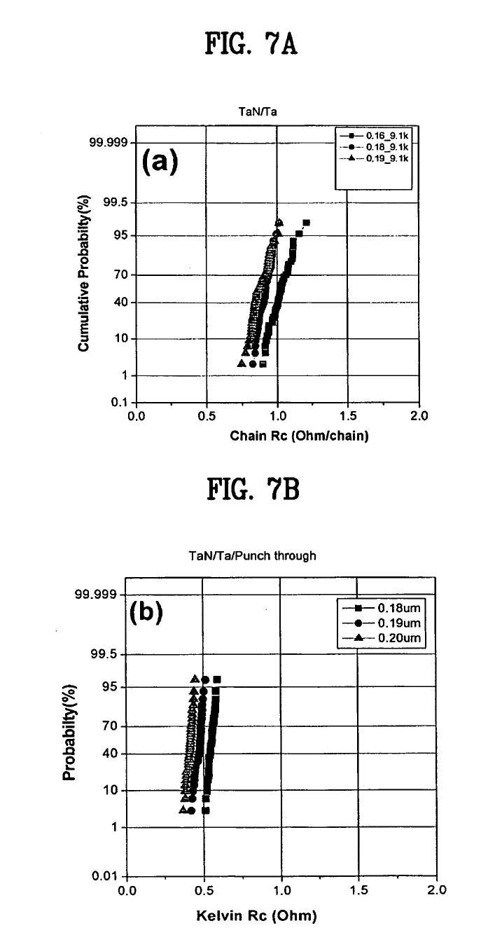

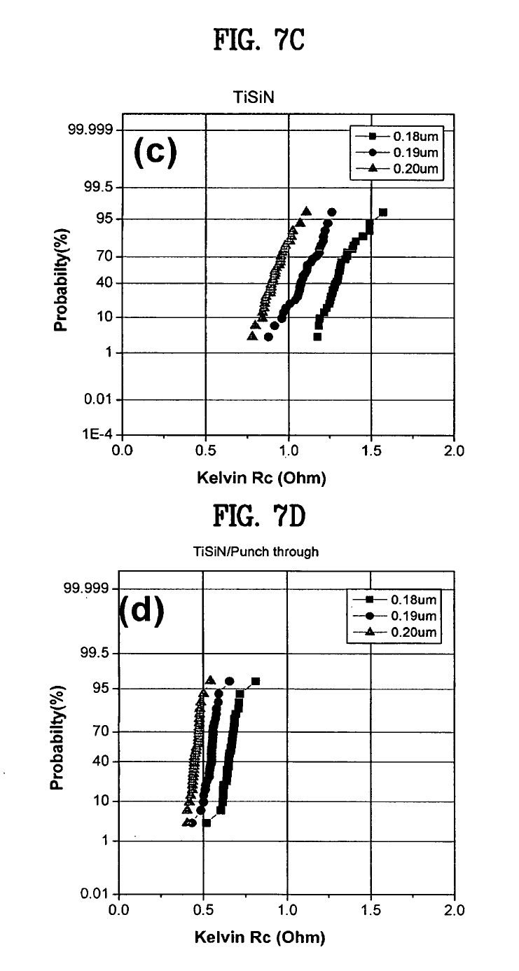

Also, a Kelvin resistance has been analyzed with respect to the structure of FIG. 6, the results are shown in FIGS. 7A to 7D.

FIG. 7A shows the results associated with not using a punch-through process in the Ta/TiN structure of the prior art. FIG. 7B shows the results with using a punch-through process in the Ta/TiN structure of the prior art. FIG. 7C shows the results with not using a punch-through process in the TiSiN structure of the present invention. FIG. 7D shows the results with using a punch-through process in the TiSiN structure of the present invention.

As in the case of the aforementioned chain resistance, it has been confirmed that, if the punch-through process is used in the TiSiN barrier metal layer of the present invention, the Kelvin resistance may also reduced.

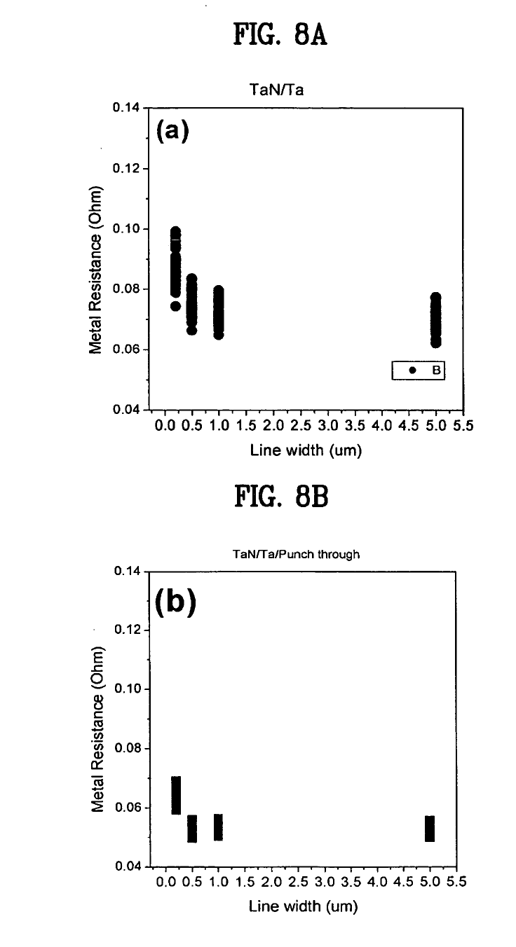

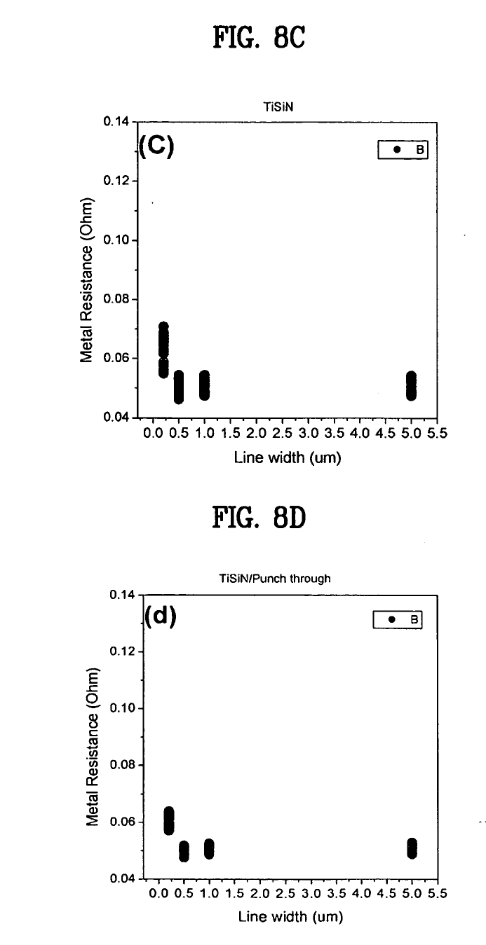

In addition, a resistance distribution based on a line width in the structure of FIG. 6 has been analyzed, which can be seen in FIGS. 8A to 8D.

FIG. 8A shows the results associated with not using a punch-through process in the Ta/TiN structure according to the prior art. FIG. 8B shows the results with using a punch-through process in the Ta/TiN structure of the prior art. FIG. 8C shows the results with not using a punch-through process in the TiSiN structure of the present invention. FIG. 8D shows the results with using a punch-through process in the TiSiN structure of the present invention.

It has been confirmed that the least resistance distribution can be seen in the case of using the punch-through process in the TiSiN structure of the present invention unlike other cases.

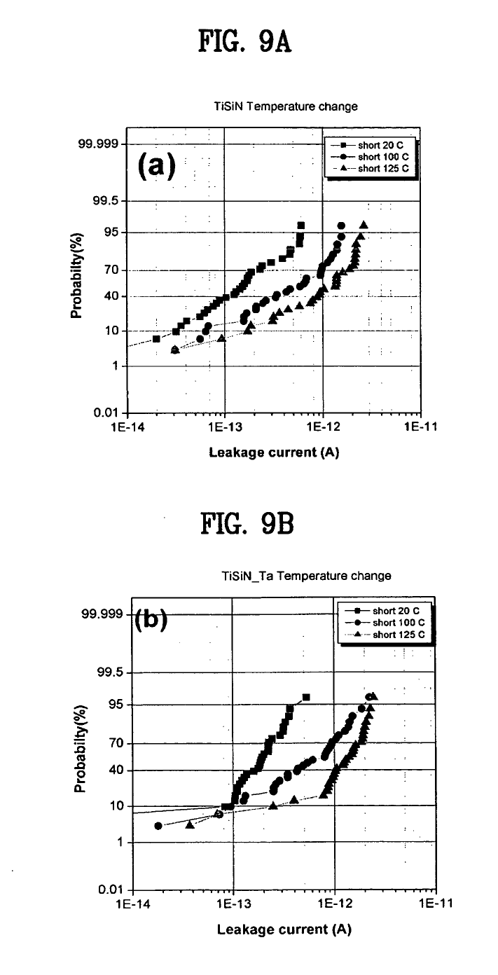

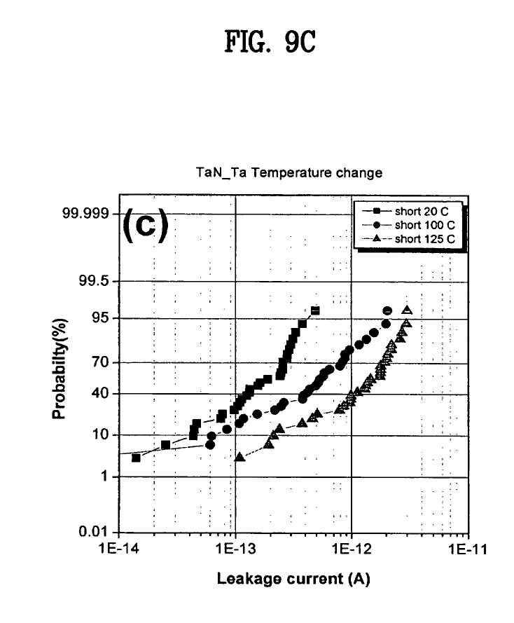

In addition, a leakage current has been analyzed based on a temperature with respect to the structure of FIG. 6, which can be seen in FIGS. 9A to 9C.

FIG. 9A shows a result for the case of a single structure of TiSiN according to a first embodiment of the present invention. FIG. 9B shows a result for the case of the Ta/TiSiN structure according to a second embodiment of the present invention. FIG. 9C shows a result for the case of the Ta/TiN structure according to the prior art.

It has been confirmed that the structure according to the second embodiment of the present invention has the least leakage current.

Accordingly, a metal line for a semiconductor device of the present invention and a fabrication method thereof may have the following advantages.

First, even if TiSiN or Ta/TiSiN is shallowly formed as an anti-diffusion layer for a Cu line in the present invention, a metal layer can be formed for a semiconductor device less than 65 nm deep, since characteristics of copper diffusion, adhesion, and resistance are excellent.

Second, additional apparatuses are not required since CVD TiSiN can be formed by adding a simple gas delivery system on TiN which is currently used as a barrier metal layer. Thus, a metal line for a semiconductor device less than 65 nm deep can be fabricated in a processing line for a semiconductor device around 90 nm deep at the minimum cost.

It will be apparent to those skilled in the art that various modifications and variations can be made in the present invention without departing from the spirit and scope of the invention. Thus, it is intended that the present invention cover the modifications and variations of this invention provided they come within the scope of the appended claims and their equivalents.

What is claimed is:

1. A metal line for a semiconductor device comprising:
a semiconductor substrate having a semiconductor device formed thereon;
an insulating layer which has a contact hole at a portion corresponding to the semiconductor device and is formed on the semiconductor substrate;
a TiSiN barrier metal layer which is formed in the contact hole; and
a copper line which is formed on the TiSiN barrier metal layer.

2. The metal line according to claim 1, wherein the TiSiN barrier metal layer is formed on a portion other than the bottom of the contact hole.

3. The metal line according to claim 1, wherein the TiSiN barrier metal layer has a thickness of 30 to 100 Angstroms.

4. The metal line according to claim 1, wherein the contact hole has a dual damascene structure.

5. A metal line for a semiconductor device comprising:
a semiconductor substrate having a semiconductor device formed thereon;
an insulating layer which has a contact hole at a portion corresponding to the semiconductor device and is formed on the semiconductor substrate;
a barrier metal layer which comprises a TiSiN layer formed in the contact hole and a Ta layer laminated on the TiSiN; and
a copper line which is formed on the barrier metal layer.

6. The metal line according to claim 5, wherein the TiSiN barrier metal layer is formed on a portion other than the bottom of the contact hole.

7. The metal line according to claim 5, wherein the TiSiN layer has a thickness of 30 to 100 Angstroms.

8. The metal line according to claim 5, wherein the Ta layer has a thickness of 30 to 100 Angstroms.

9. The metal line according to claim 5, wherein the contact hole has a dual damascene structure.

10. A method of fabricating a metal line for a semiconductor device comprising steps of:
forming a semiconductor device on a semiconductor substrate;
forming a contact hole at a portion corresponding to the semiconductor device by depositing an insulating layer on the semiconductor substrate and selectively removing the insulating layer;
forming a TiSiN barrier metal layer on the whole surface of the semiconductor substrate including the contact hole;
forming a copper layer on the TiSiN barrier metal layer; and
grinding the copper layer and the TiSiN barrier metal layer to expose a surface of the insulating layer.

11. The method according to claim 10, further comprising a step of removing the TiSiN layer from the bottom of the contact hole by a punch-through process before the copper layer is formed.

12. The method according to claim 10, wherein the TiSiN barrier metal layer has the thickness of 30 to 100 Angstroms.

13. The method according to claim 10, wherein the step of forming the TiSiN barrier metal layer further comprises:
a first step of depositing a thermal TiN layer using a tetrakis dimethyl amino titanium (TDMAT) material;
a second step of forming a CVD nitride titanium (TiN) layer by performing a plasma process on the thermal TiN; and
a third step of forming a CVD TiSiN layer by reacting SiH₄ gas with the CVD TiN layer.

14. The method according to claim 13, further comprising a step of repeating the first and second steps to form a CVD TiN layer having a desired thickness.

15. The method according to claim 13, wherein the third step is performed in a condition where the temperature of the semiconductor substrate is maintained at 300 to 400° C.

16. A method of fabricating a metal line for a semiconductor device comprising steps of:
forming a semiconductor device on a semiconductor substrate;
forming a contact hole at a portion corresponding to the semiconductor device by depositing an insulating layer on the semiconductor substrate and selectively removing the insulating layer;
forming a TiSiN barrier metal layer on the whole surface of the semiconductor substrate including the contact hole;
forming a Ta layer on the TiSiN layer;
forming a copper layer on the Ta layer; and
grinding the copper layer, the TiSiN layer, and the Ta layer to expose a surface of the insulating layer.

17. The method according to claim 16, further comprising a step of removing the Ta layer from the bottom of the contact hole by a punch-through process before the copper layer is formed.

18. The method according to claim 16, wherein the TiSiN layer and the Ta layer respectively have a thickness of 30 to 100 Angstroms.

19. The method according to claim 16, wherein the step of forming the TiSiN barrier metal layer further comprises:
a first step of depositing a thermal TiN layer using a tetrakis dimethyl amino titanium (TDMAT) material;
a second step of forming a CVD nitride titanium (TiN) layer by performing a plasma process on the thermal TiN; and
a third step of forming a CVD TiSiN layer by reacting SiH₄ gas with the CVD TiN layer.
